(19) United States
(12) Patent Application Publication
(10) Pub. No.: US 2001/0040464 A1
(43) Pub. Date: Nov. 15, 2001

(54) ELECTRIC CONTACT DEVICE FOR TESTING SEMICONDUCTOR DEVICE

(76) Inventors: MICHINOBU TANIOKA, TOKYO (JP); HIROSHI MATSUOKA, TOKYO (JP)

Correspondence Address: SUGHRUE MION ZINN MACPEAK & SEAS, 2100 PENNSYLVANIA AVENUE NW, WASHINGTON, DC, 20037

(21) Appl. No.: 09/460,977

(22) Filed: Dec. 15, 1999

(30) Foreign Application Priority Data
Dec. 15, 1998 (JP) 10-355894

(51) Int. Cl. G01R 31/26

(52) U.S. Cl. 324/765

(57) ABSTRACT

An electric contact device for testing a semiconductor device including pads or bumps including: a contacting sheet having bumps or pads at positions corresponding to the pads or the bumps of the semiconductor device overlying the testing substrate; and an elastic conductive sheet for generating contact between the semiconductor device and the contact sheet. Damage of external terminals of the semiconductor device can be minimized to delete a harmful influence on the next step.

### BACKGROUND OF THE INVENTION

(a) Field of the Invention

The present invention relates to an electric contact device for testing a semiconductor device, more in detail, to the electric contact device for testing the semiconductor device without damaging external terminals of the semiconductor device.

(b) Description of the Related Art

In a selection step and a burn-in step in testing steps of a semiconductor device, external terminals of the semiconductor device to be tested are in contact with a testing probe. A metal pin, a metal wire embedded in a sheet or a bump mounted on a sheet (so-called membrane sheet) is employed as the testing probe.

The testing steps of the semiconductor device will be described referring to FIG. 1. After brief testing of a wafer, a chip is subjected to dicing. After a step of assembling a package, a first testing step (first selection) is conducted for removing defective wafers generated in the assembly. Then, a burn-in step is conducted at a higher temperature, for example, 125° C. for 16 hours under a stress. A second testing step (second selection) is conducted for removing inferior wafers generated in the burn-in, and the remaining wafers are shipped.

A conventional electric contact device for testing a semiconductor device employed in the first selection, the burn-in and the second selection will be described referring to FIG. 2. The testing apparatus includes contact pins 10 made of a metal which are slanted for producing a spring action. The bases of the contact pins 10 reach to guiding apertures through a guide 11. The top ends of the contact pins 10 project from the top surface of the guide 11. The bottoms of the respective contact pins 10 are electrically connected to a test board, a BT board or its extension substrate.

When an arrangement pitch between the external terminals is 0.5 mm or less in the conventional semiconductor device to be tested having the pins, the pins having the spring action are hardly manufactured. If the spring action is provided to the pins, a problem such that (1) the pin having a longer length increases a resistance, to generate a signal delay so that a response to a high frequency is difficult, and (2) the manufacturing cost of the pins is very high because the pins are handmade, may arise.

A conventional electric contact device for testing a semiconductor device shown in FIG. 3 includes a metal wire embedded sheet 14 in which metal thin wires 15 made of phosphor bronze, BeCu or brass are embedded in silicone resin 16 having elasticity such that the both ends of the metal thin wires are exposed to the both surfaces of the sheet 14. The sheet 14 is placed on an extension substrate 17 for testing. The metal wire embedded sheet 14 is generally known as an anisotropic conductive sheet (JP-A-5(1993)-259238).

A semiconductor device 18 to be tested, such as a bare chip and a chip scale package (CSP), includes pads or solder bumps as external terminals 19 and is pressed onto the sheet 14. At this time, the external terminal 19 or the pad of the semiconductor device 18 is pressed against the top surface of the sheet 141 so that the external terminal 19 and the metal thin wire 15 are in contact with each other. As shown in an enlarged portion of FIG. 3, the top ends of the metal thin wires 15 exposing to the surface of the silicone resin have a shape of an acute angle which sticks in the external terminals. Accordingly, the following problems may arise. (1) The external terminal is damaged to exert a harmful influence on the next step. If, for example, the external terminal is the pad having a damage, a wetting ability of the solder may become poor or a void is formed at the time of placing the solder bump on the pad. (2) The pad is peeled off which is then adhered as a waste to the testing apparatus to lower a durability thereof. When the external terminal is the solder bump, a contact deficiency may occur by the bump waste generated by a number of contacts to the solder bump.

A conventional electric contact device for testing a semiconductor device shown in FIG. 4 includes a contact sheet 20 having bumps 21. The bumps 21 and pads 22 are mounted on the top and the bottom surfaces of the sheet 20, respectively, and are connected with each other by conductive materials filled in through-holes. An example of the sheet having the bumps is described in JP-A-10(1998)-178074.

In FIG. 4, a semiconductor device 23 to be tested is placed on the sheet 20 and pressurized such that external terminals (pads) 24 of the semiconductor device 23 are pressed against the sheet 20 and are in contact with the bumps 21. The sheet 20 is required to have elasticity in order to obtain a good contact between the external terminal and the bump for absorbing unevenness of the heights of the bumps and non-flatness of semiconductor device 23. However, the conventional contact sheet 20 having the bumps lacks the elasticity. When an elastic member is disposed right below the bump 21 of the sheet 20 in order to provide the elasticity, electric connection of the bump 21 to an extension substrate 25 cannot be attained because of the existence of the elastic member. In order to achieve the electric connection, an interconnect should be outwardly taken. In case of a semiconductor device including a multiple pin area pad arrangement (for example, a device including external terminals having 2000 pins or more and a pitch of 0.5 mm or less) having a multiple-layered substrate as the sheet 20, interconnects extending to its periphery and external terminals connected to the extension substrate 25, a manufacturing cost thereof is greatly increased because the sheet 20 becomes extremely larger. The multi-layered extension substrate 25 becomes rigid to lose the elasticity so that the stable contact cannot be obtained.

The above-mentioned problems also exist in the conventional devices employing the pins, the metal wire embedded sheet or the contact sheet.

### SUMMARY OF THE INVENTION

In view of the foregoing, an object of the present is to provide an electric contact device for testing a semiconductor device which can obtain a secure contact between electric elements without damaging external terminals of the semiconductor device.

Another object of the present invention is to provide the electric contact device for testing the semiconductor device having the external terminals of which a pitch is 0.5 mm or less, and more preferably 0.2 mm or less.

The present invention provides, in a first aspect thereof, an electric contact device for use in a test apparatus for testing a semiconductor device halving a plurality of external terminals thereon, said electric contact device comprising a contact sheet having a top surface mounting thereon a plurality of first test terminals to be in contact with the external terminals and a bottom surface mounting thereon a plurality of second test terminals and electrically connected to respective said first test terminals, and an elastic conductive sheet having a top surface mounting thereon a plurality of third terminals in contact with respective said second terminals and a bottom surface mounting thereon a plurality of fourth terminals electrically connected to respective said third terminals.

The present invention provides, in a second aspect thereof, an electric contact device for use in a test apparatus for testing a semiconductor device having pads as external terminals including: a testing substrate to be in contact with the semiconductor device; a metal wire embedded sheet including an elastic material and metal wires is embedded therein of which a top end is exposed; and a plurality of bumps positioned on the top ends of the metal wires opposite to the external terminals of the semiconductor device.

In accordance with the electric contact device for testing the semiconductor device, damage of the external terminals of the semiconductor device can be made minimum to delete a harmful influence on the next step by the combination of the contact sheet and the metal wire embedded sheet or of the contact sheet and the plurality of the bumps.

Further, the electric contact device realizes a secure contact between the semiconductor device and the extension substrate without damaging the external terminals of the semiconductor device. The electric contact device is especially effective when the semiconductor device to be tested includes multiple pins in a matrix configuration.

The above and other objects, features and advantages of the present invention will be more apparent from the following description.

### BRIEF DESCRIPTION OF DRAWINGS

FIG. 1 is a flow chart showing an entire feature of conventional testing steps.

FIG. 2 is an enlarged vertical sectional view showing a conventional electric contact device for testing a semiconductor device employing metal pins.

FIG. 3 is a vertical sectional view showing a conventional electric contact device for testing a semiconductor device employing a metal wire embedded sheet.

FIG. 4 is a vertical sectional view showing a conventional electric contact device for testing a semiconductor device employing a contact sheet.

FIG. 5 is a vertical sectional view showing an electric contact device for testing a semiconductor device in accordance with a first embodiment of the present invention.

FIG. 6 is a partially enlarged view of a contact sheet of FIG. 5.

FIG. 7 is a vertical sectional view showing an electric contact device for testing a semiconductor device in accordance with a second embodiment of the present invention.

FIG. 8 is a vertical sectional view showing an electric contact device for testing a semiconductor device in accordance with a third embodiment of the present invention.

FIG. 9 is a sectional view showing another example of a metal wire embedded sheet of the present invention.

FIG. 10 is a sectional view showing a further example of the metal wire embedded sheet of the present invention.

### PREFERRED EMBODIMENTS OF THE INVENTION

Now, the present invention is more specifically described with reference to accompanying drawings.

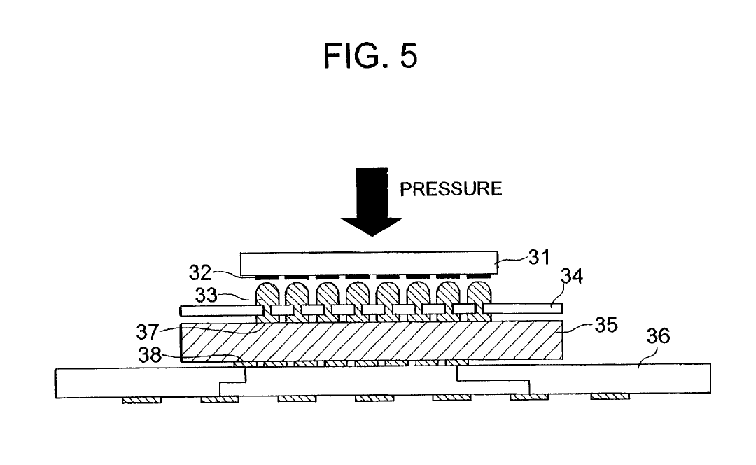

An electric contact device for testing shown in FIG. 5 in accordance with a first embodiment of the present invention is suitably employed for a semiconductor device having pads as external terminals (LGA: Land Grid Array).

The electric contact device includes a contact sheet 34 having bumps 33 thereon and a metal wire embedded sheet 35. The top surface of the contact sheet 34 mounts thereon bumps 33 at positions corresponding to external terminals 32 of a semiconductor device 31 to be tested. The bottom surface of the contacting sheet 34 mounts thereon pads 37 connected to the bumps 33 via through-hole conducting materials.

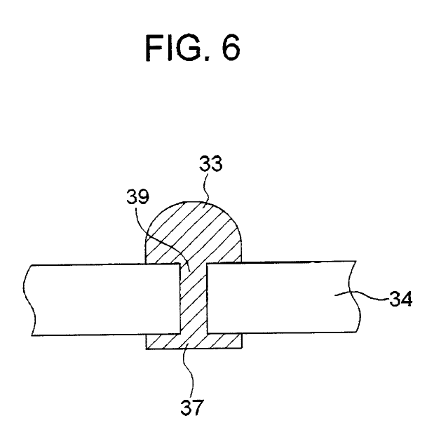

In FIG. 6 showing the electrical connection between the bump 33 and the pad 37 through the conductive material, the contact sheet 34 is formed of a copper-clad polyimide sheet. The pad 37 is made of copper remaining on the polyimide sheet or a nickel-based alloy, and a through-hole conductive material 39 and the bump 33 are formed after the growth of the copper or the nickel-based alloy inside of and on the through-hole over the pad 37 by means of electrolytic plating.

Since the copper has an insufficient hardness and is likely to be oxidized to form an oxidized film to impede a smooth contact with another material, the bump 33 and the pad 37 are plated with nickel or a Ni/Pd alloy to increase the hardness and further plated with gold to improve the contact with another material. The bump plated in this manner has, for example, a diameter of about 80 μm and a height of 30 to 40 μm.

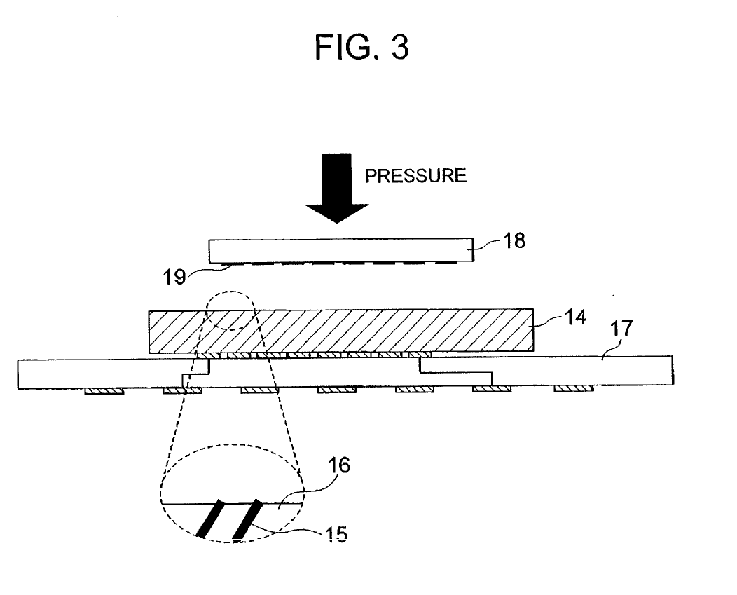

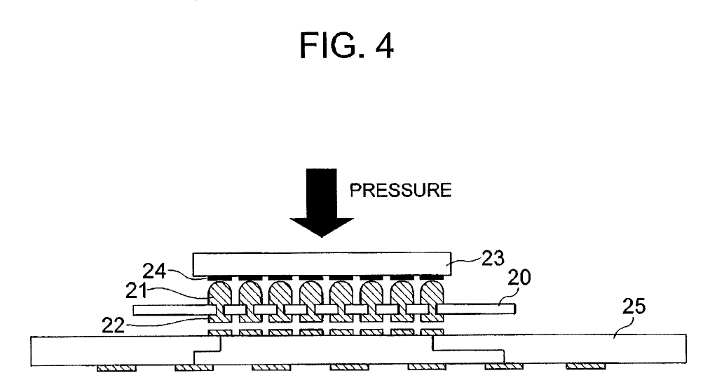

The metal wire embedded sheet 35 has a similar configuration to that described referring to FIG. 3. That is, the metal wire embedded sheet 35 includes an elastic silicone resin sheet having a thickness of about 1 mm and a plurality of metal thin wires having a diameter of about 20 to 40 μm made of phosphor bronze, BeCu or brass embedded in the silicone resin sheet and slanted with respect to the surface of the sheet such that the both ends of the metal thin wires are exposed to the both surfaces of the sheet 35. The slanted arrangement of the metal thin wires creates a spring action and improves a durability.

The contact sheet 34 and the metal wire embedded sheet 35 are placed on an extension substrate 36 for testing or a substrate for testing and burn-in. At this stage, the top ends of the metal thin wires of the top surface of the metal wire embedded sheet 35 are in contact with the pads 37 of the rear surface of the contact sheet 34, and the bottom ends of the metal thin wires of the bottom surface of the metal wire embedded sheet 35 are in contact with pads 38 on the extension substrate 36.

At the time of testing, the semiconductor device 31 is placed on the contact sheet 34 and pressurized to make contact between the external terminals (pads) 32 and the bumps 33 of the contact sheet 34. Thereby, the external terminals 32 are electrically connected to the extension substrate 36 by way of the contacting sheet 34 and the metal wire embedded sheet 35.

In accordance with the structure of the present embodiment, the external terminals and the bump are securely connected by absorbing the unevenness of the heights of the bumps and the non-flatness of the semiconductor device by means of the elasticity of the metal wire embedded sheet without providing the damages to the external terminals of the semiconductor device having the multiple pins

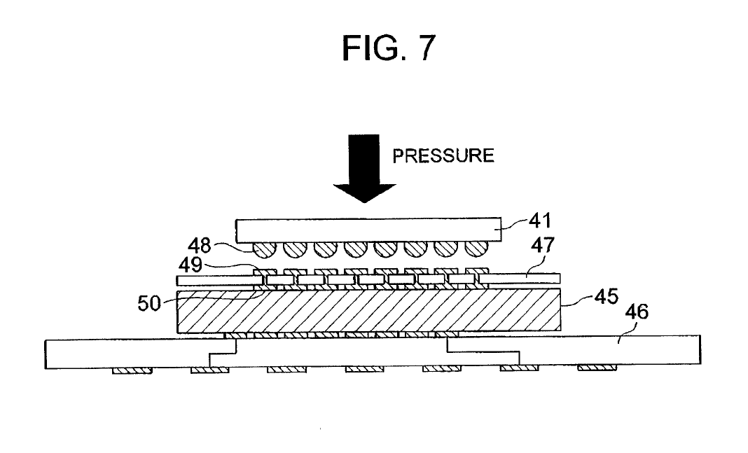

An electric contact device shown in FIG. 7 in accordance with a second embodiment of the present invention is suitably employed for a semiconductor device having solder bumps as external terminals (BGA: Ball Grid Array)

The device includes a contact sheet 47 and a metal wire embedded sheet 45. The contacting sheet 47 made of polyimide, similar to that of the first embodiment, includes pads 49 and 50 on the both surfaces thereof connected with each other by way of through-hole materials made of copper. These pads 49 and 50 are formed by applying nickel or a Ni/Pd alloy and gold onto the copper.

In the second embodiment different from the first embodiment, the pads 49 are placed in place of bumps on the top surface of the contacting sheet 47. Since the external terminals of the semiconductor device 41 are the spherical bumps 48, the spherical bumps slip each other not to provide an excellent contact therebetween if the terminals of the contacting sheet are the spherical bumps shown in the first embodiment.

The metal wire embedded sheet 45 is similar to that of the first embodiment. The electric contact device for testing the semiconductor device is formed by disposing the contacting sheet 47 on the metal wire embedded-sheet 45.

Since, in accordance with the configuration of the present embodiment, the spherical solder bumps 48 which are the external terminals of the semiconductor device 41 is in contact with the pads 49 of the contacting sheet 47 having flat surfaces, the semiconductor device 41 can be in contact with the metal wire embedded sheet 45 without damaging the solder bumps 48. Accordingly, smooth testing of the semiconductor device can be conducted.

In the first and the second embodiments, the terminal of the top surface of the contact sheet is the bump or the pad depending on whether the external terminal of the semiconductor device is the pad or the bump, respectively. On the other hand, the bottom terminal of the contacting sheet may be either of the pad or the bump because the terminal can be only in contact with the top ends of the metal thin wires on the top surface of the metal wire embedded sheet.

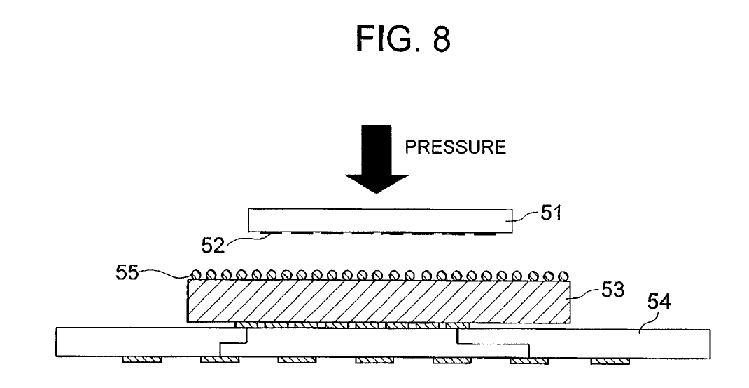

An electric contact device shown in FIG. 8 in accordance with a third embodiment of the present invention includes a plurality of fine bumps 55 at the top ends of metal thin wires embedded in a metal wire embedded sheet 53 opposing to external terminals 52 of a semiconductor device 51. The metal wire embedded sheet 53 is prepared by improving the conventional anisotropic conductive sheet shown in FIG. 3.

The fine bumps 55 may be prepared by adsorbing fine balls made of gold on the top ends of the metal thin wires, plating nickel or a Ni/Pd alloy thereon for elevating a hardness and adhering the fine balls to the top ends of the metal thin wires under heating. Fine balls made of copper plated with nickel or a Ni/Pd alloy and further with gold or fine balls made of copper having a thin plated layer thereon may be employed in place of the fine balls made of the gold. When the latter fine balls made of the copper is employed, the thin plated layer is melted by the heating to expose the surface of the balls onto which gold may be plated.

In accordance with the present embodiment, the damage to the external terminals of the semiconductor device can be made minimum by the combination of the elastic sheet and the bumps to delete a harmful influence on the next step.

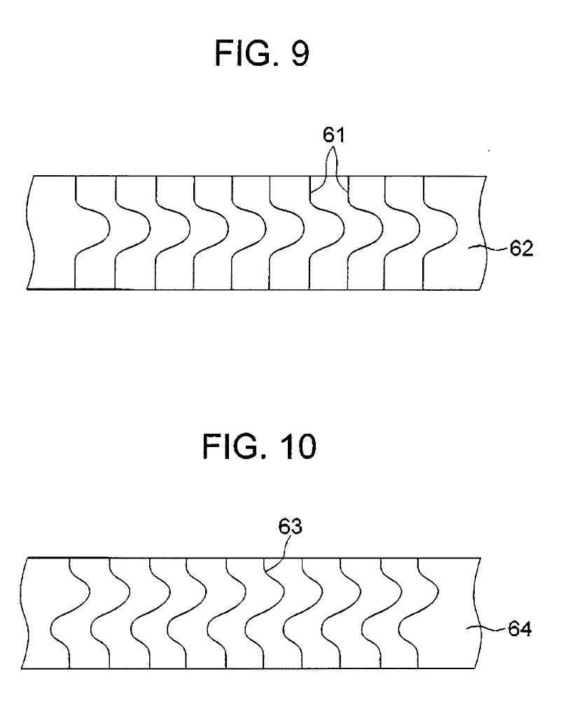

The metal wire embedded sheet employed in the above three embodiments has a structure! of producing the spring action by linearly slanting- the metal thin wires, but the arrangement of the metal thin wires is not restricted thereto and other arrangements for producing the elasticity are exemplified in FIGS. 9 and 10.

In a metal wire embedded sheet shown in FIG. 9, metal thin wires 61 having a U-shaped curve for generating the spring action are embedded in a silicone resin sheet 62.

In another metal wire embedded sheet shown in FIG. 10, metal thin wires 63 having an S-shaped curve for generating the spring action are embedded in a silicone resin sheet 64.

In addition thereto, any configuration generating the spring action may be employed.

Then, the testing steps which employ the electric contact device for testing the semiconductor device in accordance with the present invention will is be exemplified.

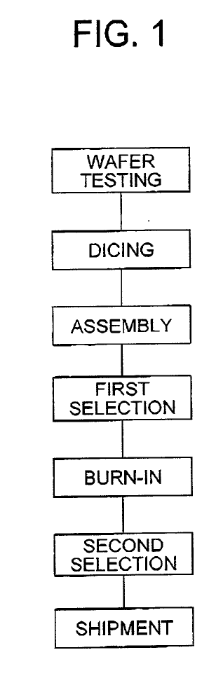

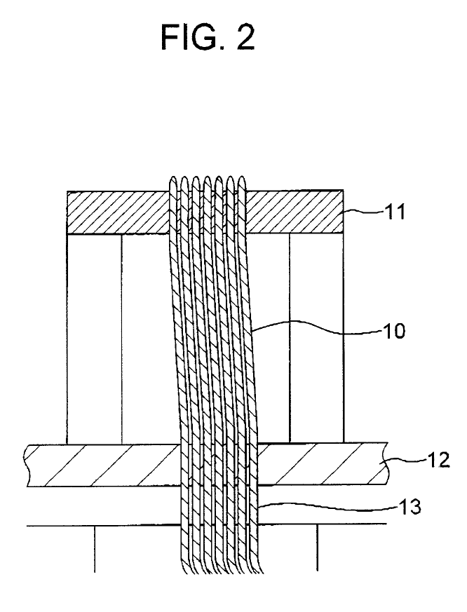

The testing steps include the (first and second) selection steps and the burn-in step as shown in FIG. 1. The electric contact device of the present invention can be applied to both of the steps. The electric contact device for the selection steps requires the metal thin wires in the metal wire embedded sheet having a short length because testing conducted as rapid as possible is needed. The longer testing increases an inductance to provide a signal delay. The testing is conducted while the semiconductor device is pressurized employing a handler. The testing by employing the electric contact device for the burn-in step is conducted under a higher temperature while the semiconductor device is pressurized. Therefore, the electric contact device for testing the semiconductor device is required to have a specified degree of thermal stability.

Then, the whole testing steps employing the electric contact device for testing the semiconductor device of the first embodiment will be described.

The semiconductor device after the wafer testing, the dicing and the assembly is recognized, with a camera, by the bump or an interconnect pattern of the contact sheet or a recognition mark of the semiconductor device. After the alignment of the semiconductor device on the contact sheet the first selection is conducted while the pressurized condition is maintained. The unevenness of the bump heights and the non-flatness of the semiconductor device are absorbed by the metal wire embedded sheet. The semiconductor device to be tested is a bare chip before the assembly or a CSP after the assembly. Upon completion of the first selection, the position alignment between a burn-in socket and the semiconductor device is similarly conducted for mounting the semiconductor device. After the outer periphery of the semiconductor device is retained under pressure and a socket cover having a pressing mechanism is equipped, the pressurization is released. The semiconductor device including a board is thrown into a burn-in device retaining the above state. Upon the completion of the burn-in, the semiconductor device is taken off from the burn-in socket in accordance with procedures in the reverse order, and the second selection is conducted similarly to the first selection. In accordance with the above steps, the testing of the semiconductor device having the multiple pins in a narrow pitch arrangement can be performed.

When the external terminal of the semiconductor device is implemented by a pad, substantially no defect is generated in the contact function of the pad during the testing. When, accordingly, solder balls are attached to the pads, for forming solder bumps in later steps, a deficiency in connection with solder wetting due to the contact injury can be prevented to elevate reliability.

When the external terminal of the semiconductor device implemented by is a bump, a connection deficiency can be prevented due to crush of the balls generated by a contact pressure applied to the solder bump. The elasticity of the metal wire embedded sheet absorbs the unevenness of the bump heights and the non-flatness of the semiconductor device to obtain a secure contact.

Since the above embodiments are described only for examples, the present invention is not limited to the above embodiments and various modifications or alternations can be easily made therefrom by those skilled in the art without departing from the scope of the present invention.

What is claimed is:

1. An electric contact device for use in a testing apparatus for testing a semiconductor device having a plurality of external terminals thereon, said electric contact device comprising a contact sheet having a top surface mounting thereon a plurality of first test terminals to be in contact with the external terminals and a bottom surface mounting thereon a plurality of second test terminals and electrically connected to respective said first test terminals, and an elastic conductive sheet having a top surface mounting thereon a plurality of third terminals in contact with respective said second terminals and a bottom surface mounting thereon a plurality of fourth terminals electrically connected to respective said third terminals.

2. The electric contact device as defined in claim 1, further comprising a substrate mounting thereon said contact sheet and said elastic sheet, said substrate having a top surface mounting thereon a plurality of fifth terminals in contact with respective said fourth terminals and a bottom surface mounting thereon a plurality of sixth terminals electrically connected to the fifth terminals.

3. The electric contact device as defined in claim 1, wherein said first terminals are connected to respective said second terminals via through-holes.

4. The electric contact device as defined in claim 1, wherein said third terminals are connected to respective said fourth terminals via metallic wires.

5. The electric contact device as defined in claim 1, wherein said first terminals include bumps.

6. The electric contact device as defined in claim 1, wherein said first terminals include pads.

7. The electric contact device as defined in claim 1, wherein the elastic conductive sheet is an anisotropic conductive sheet including an elastic material and metal wires embedded therein.

8. The electric contact device as defined in claim 5, wherein the bumps include copper, nickel or a nickel alloy plated thereon and gold further plated thereon.

9. An electric contact device for use in a test apparatus for testing a semiconductor device including pads as external terminals comprising:
a testing substrate to be in contact with the semiconductor device;
a metal wire embedded sheet including an elastic material and metal wires embedded therein of which a top end is exposed; and
a plurality of bumps positioned on the top ends of the metal wires opposite to the external terminals of the semiconductor device.

10. The electric contact device as defined in claim 9, wherein the plurality of bumps include gold balls and nickel or a nickel alloy plated thereon.

11. The electric contact device as defined in claim 9, wherein the plurality of bumps include copper balls, nickel or a nickel alloy plated thereon and gold further plated thereon.

12. The electric contact device as defined in claim 9, wherein the plurality of bumps include copper balls and gold plated thereon.

13. The electric contact device as defined in claim 9, wherein the metal wires are arranged to have a spring action.

14. The electric contact device as defined in claim 9, wherein the metal wires are slanted with respect to the surface of the metal wire embedded sheet.

15. The electric contact device as defined in claim 9, wherein the metal wires have a U-shaped curve.

16. The electric contact device as defined in claim 9, wherein the metal wires have an S-shaped curve.
